(19) United States
(12) Patent Application Publication
(10) Pub. No.: US 2015/0189770 A1
(43) Pub. Date: Jul. 2, 2015

(54) System for Attaching RFIDs on Tires

(71) Applicant: Justin Thomas Loop, Friendswood, TX (US)

(72) Inventor: Justin Thomas Loop, Friendswood, TX (US)

(21) Appl. No.: 14/141,385

(22) Filed: Dec. 26, 2013

(51) Int. Cl. H05K 5/00

(52) U.S. Cl. CPC H05K 5/0091

(57) ABSTRACT

A system for attaching RFIDs on tires is herein disclosed. In this embodiment, the system for attaching RFIDs on a tire comprises a base, and an RFID housing. The base comprising an orifice. The base capable of affixing to a tire. The RFID housing capable of substantially fitting within the orifice.

### BACKGROUND

This disclosure relates to a system for attaching RFIDs on tires.

Inventory systems have been developed to manage, supervise, and control items of any business organization. Furthermore, inventory systems enable business owners to monitor assets and inventories as well as the costs associated for each entity. Thus in a fleet facility, monitoring of assets such as tractors and trailers are essential. However, consumables such as tires, which are related to an asset, are often neglected. As a result, new tires are often being stolen or exchanged for bad tires. Furthermore tracking tires are important, as tires can be one of the largest contributors to the operating cost for businesses involving large numbers of fleet vehicles. However, manually checking each tire can be inefficient and time consuming. Moreover, for fleet facilities, it can be useful to have a system that can monitor covered mileage for every tire as it can be used for claiming warranty or reimbursements. Today, with the help of the latest technology, tires can now be monitored through RFIDs. However for fleet vehicles that utilize multiple tires, detecting RFIDs can be one of the problems. As such, it would be useful to have a system for attaching RFIDs on tires.

### SUMMARY

A system for attaching RFIDs on tires is herein disclosed. In this embodiment, the system for attaching RFIDs on a tire comprises a base, and an RFID housing. The base comprising an orifice. The base capable of affixing to a tire. The RFID housing capable of substantially fitting within the orifice.

### BRIEF DESCRIPTION OF THE DRAWINGS

FIG. 1 illustrates a fleet facility.

FIG. 2A illustrates a truck embodiment of a vehicle comprising RFIDs.

FIG. 2B illustrates how an RFID can be placed on a single tire embodiment.

FIG. 2C illustrates how an RFID can be placed on a dual tire embodiment.

FIG. 3A illustrates an embodiment of a patch comprising an RFID.

FIG. 3B illustrates an assembled embodiment of a patch.

FIG. 3C illustrates another embodiment of a patch.

FIG. 4 illustrates a mobile depreciating asset system.

FIG. 5 illustrates a schematic diagram of a server.

FIG. 6 illustrates a device data store.

FIG. 7A illustrates items comprising asset information.

FIG. 7B illustrates an asset status comprising an in-service status and an out-of-service status.

FIG. 8A illustrates a tag operation mode screen that displays a read tag tab.

FIG. 8B illustrates a tag operation screen that displays a write asset information tab.

FIG. 8C illustrates a tag operation screen that displays a write tire information tab.

FIG. 9 illustrates an exemplary method for tracking consumable items.

FIG. 10 illustrates an exemplary method for setting up a mobile depreciating asset system.

FIG. 11 illustrates an exemplary method for removing a child item from a parent item.

### DETAILED DESCRIPTION

Described herein is a system for attaching RFIDs on tires. The following description is presented to enable any person skilled in the art to make and use the invention as claimed and is provided in the context of the particular examples discussed below, variations of which will be readily apparent to those skilled in the art. In the interest of clarity, not all features of an actual implementation are described in this specification. It will be appreciated that in the development of any such actual implementation (as in any development project), design decisions must be made to achieve the designers' specific goals (e.g., compliance with system- and business-related constraints), and that these goals will vary from one implementation to another. It will also be appreciated that such development effort might be complex and time-consuming, but would nevertheless be a routine undertaking for those of ordinary skill in the field of the appropriate art having the benefit of this disclosure. Accordingly, the claims appended hereto are not intended to be limited by the disclosed embodiments, but are to be accorded their widest scope consistent with the principles and features disclosed herein.

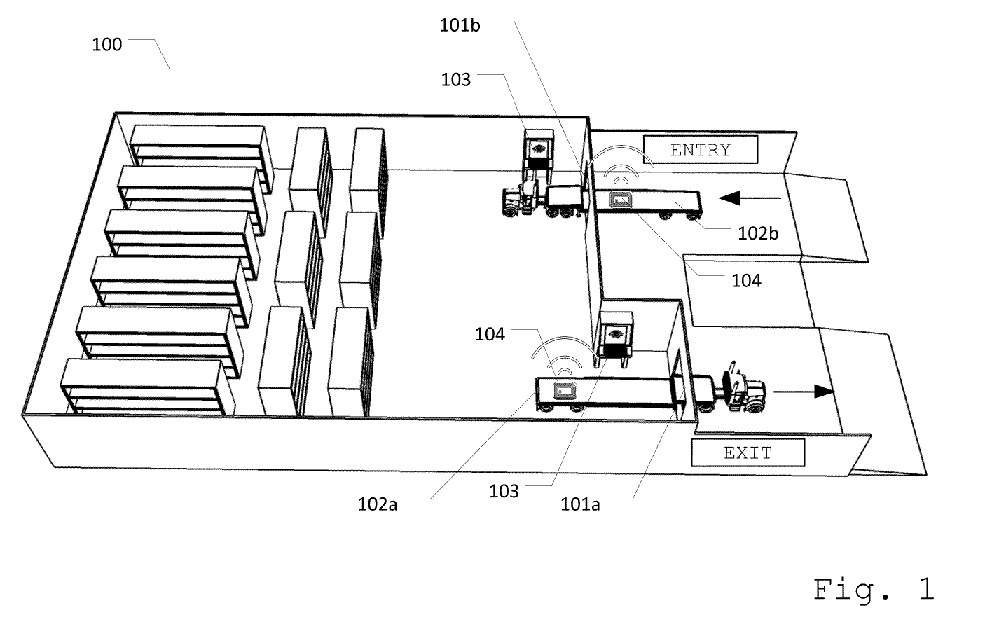

FIG. 1 illustrates a fleet facility 100 comprising one or more pass-through points 101. Fleet facility 100 can be any type of storage facility that houses for a plurality of vehicles 102, such as warehouses, shipping facilities, and factories. Pass-through points 101 can be an entrance and/or exit barrier wherein vehicles 102 can pass by or through. Furthermore, pass-through points 101 can be a border within the vicinity of fleet facility 100, wherein passing vehicles 102 can be scanned through one or more (Radio-Frequency Identification) RFID communication computers 103. In one embodiment, pass through points 101 can comprise a sensor system that allows pass through points 101 to monitor incoming and outgoing vehicles. As such, each vehicle 102 can comprise a plurality of RFIDs 104. RFID 104 can be a small electronic transceiver device that stores electronic information. RFID 104 can transfer electronic data through radio-frequency electromagnetic fields thus allowing RFID 104 to communicate wirelessly with RFID communication computer 103.

In one embodiment, RFID communication computer 103 can be an RFID reader that reads RFIDs 104 at a distance. In this embodiment, RFID communication computer 103 can receive electronic data from RFIDs 104. In another embodiment, RFID communication computers 103 can be an RFID writer that can write electronic data to RFIDs 104. In such embodiment, RFID communication computer 103 can be capable of transmitting electronic data to and receiving electronic data from RFIDs 104. Furthermore, in another embodiment, RFID communication computer 103 can be a single device that functions as an RFID writer and reader at the same time. In this embodiment, RFID communication computer can be capable of reading and writing electronic data on RFIDs 104. In such embodiments, RFID communication computer 103 can be configured to wirelessly communicate with RFIDs 104.

In one embodiment, one or more exit pass-through points 101a can be established around fleet facility 100. As such, RFID communication computers 103 can be placed at these locations. Similarly, one or more entry pass-through points 101b can be in place around the fleet facility 100. Thus, RFID communication computers 103 can also be installed at these points. In this embodiment, outgoing vehicles 102a and incoming vehicles 102b from fleet facility 100 can be scanned and monitored through RFID communication computers 103. This allows identification of unexpected activity or inactivity. Additionally, this provides organized tracking and security of assets, consumables, and inventories.

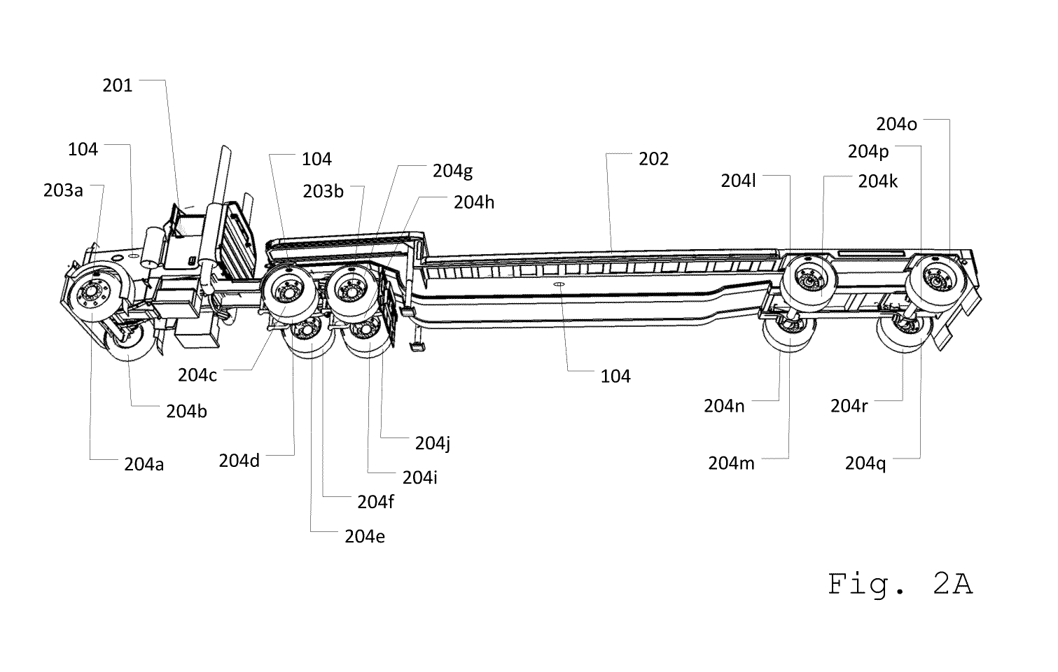

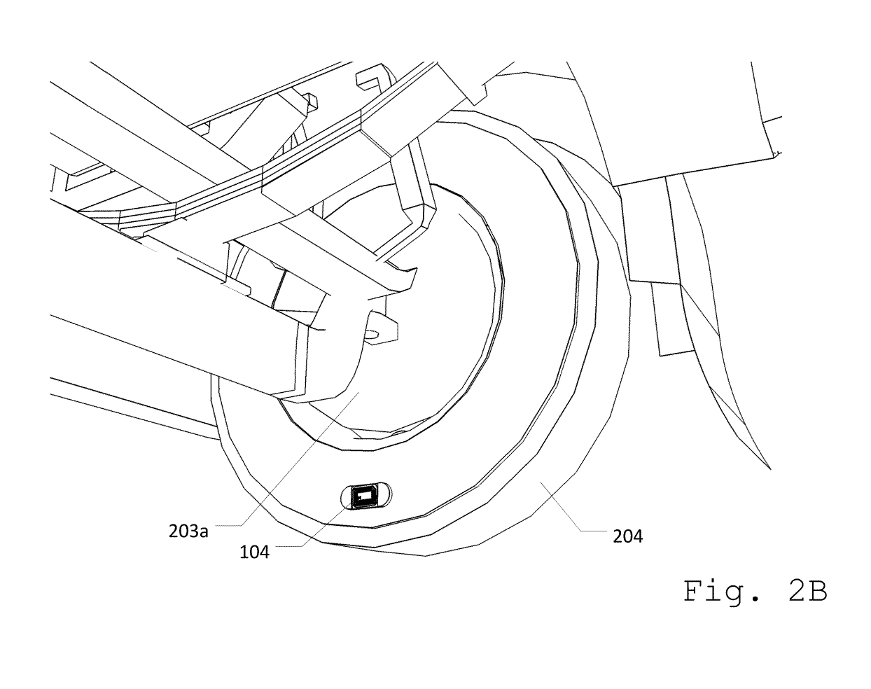

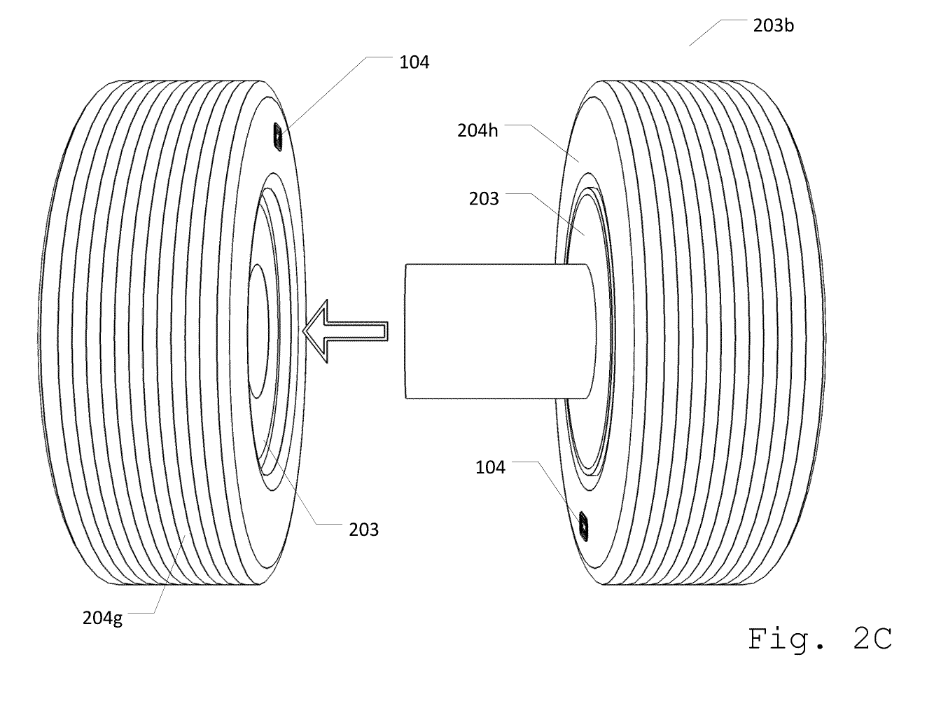

FIG. 2A illustrates a truck embodiment of vehicle 102 comprising RFIDs 104. Vehicle 102 can be any mobile machine that can be used for transport. Vehicle 102 can include but are not limited to cars, trucks, buses, and motorcycles. Moreover, vehicle 102 can be one of the fleet vehicles owned or leased by a business or government agency. In one embodiment, vehicle 102 can comprise of three main components a tractor 201, a trailer 202, and a plurality of wheels 203. Tractor 201 can be the portion of vehicle 102 that provides power to haul trailer 202. Trailer 202 can be a vehicle that can be pulled and maneuvered with tractor 201. Wheels 203 are mounted on tractor 201 and trailer 202, which allow vehicle 102 be moved to a desired location. Furthermore, wheel 203 can be categorized as a single wheel 203a or a dual wheel 203b. Further, each wheel 203 can comprise a tire 204 that serves as a functional rotational mechanism as well as a covering and protection device for wheels 203. Moreover, tire 204 provides traction between the truck and the road. As such, tire 204 can be made of durable material such as rubber that is configured to fit around each wheel 203. Additionally, tire 204 can be a consumable component of vehicle 102 that can be used and replaced once worn out. In this embodiment, tires 204a and 204b can be attached to wheels 203 of tractor 201 while tires 204c up to tires 204r can be attached to wheels 203 of trailer 202. Further, tractor 201, trailer 202, and tires 204 can each be attached with RFID 104. As an example, an 18-wheeler truck can comprise at least 20 RFIDs 104.

FIG. 2B illustrates how an RFID 104 can be placed on a single tire embodiment. In one embodiment, RFID 104 can be attached on tire 204 facing inward. In another embodiment, RFID 104 can be attached on tire 204 facing outward. These embodiments can provide protection and prevent RFID tag 104a from being damaged.

FIG. 2C illustrates how an RFID 104 can be placed on a dual tire embodiment. As an example, RFIDs 104 can be attached in between tires 204c and 204d of dual wheel 203b. This is to ensure that RFIDs 104 are protected from damage. In such embodiment, RFIDs 104 can each be placed on tires 204 offset from each other. As such, a first RFID 104 can be placed on tire 204c facing outward while a second RFID 104 can be placed on tire 204d facing inward, or vice versa. This position can prevent RFIDs 104 attached on each tires 204 from interfering with each other.

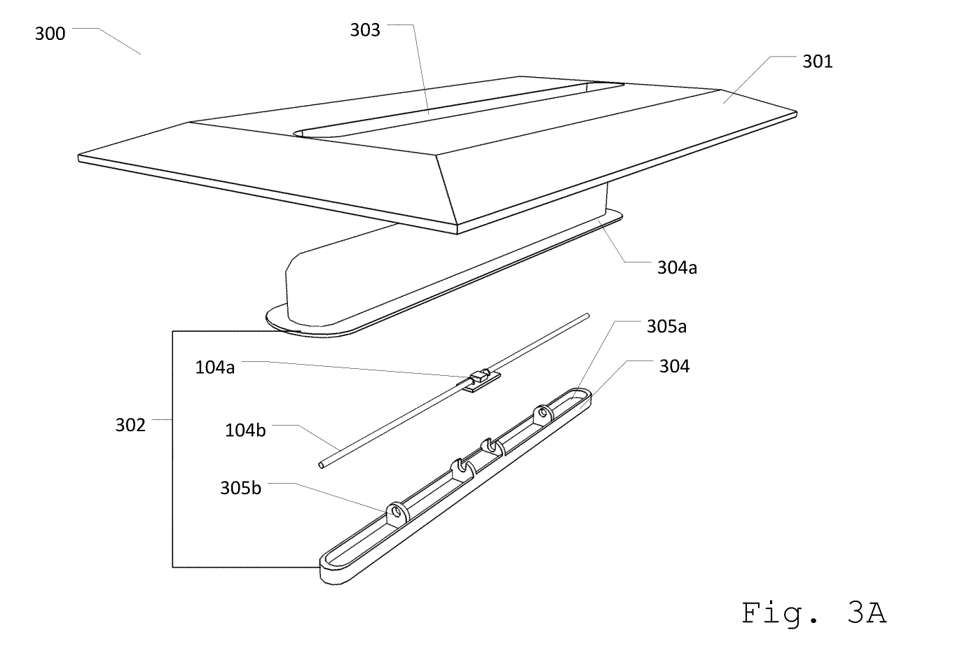

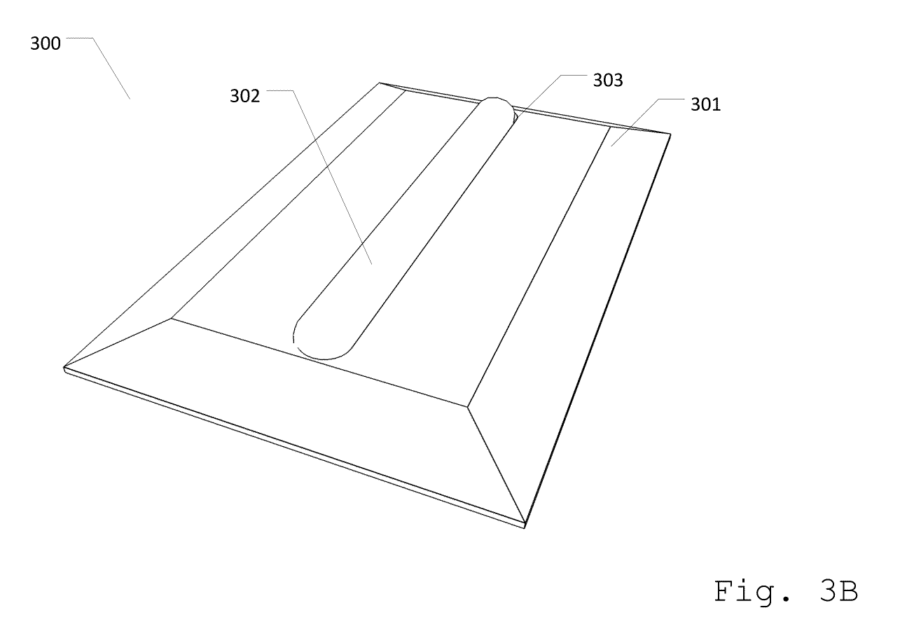

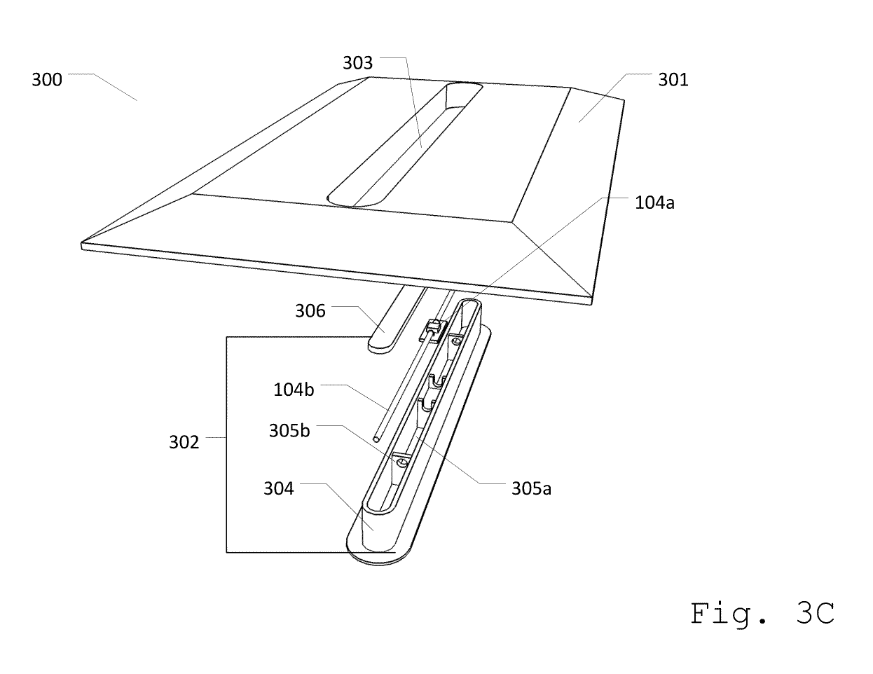

FIG. 3A illustrates an embodiment of a patch comprising RFID 104. In this embodiment RFIDs 104 can be detachable from tires 204. As such, RFIDs 104 can be attached on or in a tire 204 through adhesive, fasteners, or mechanical attachment methods. Fasteners and mechanical attachment methods can include fastening straps, snaps, and patches. In another embodiment, RFIDs 104 can be permanently attached on each tire 204. In such embodiment, RFIDs 104 can be embedded on tire 204. As such, patch 300 can be molded on tire 204. Further, patch 300 can be made from a durable material such as rubber or plastic. Patch 300 can be used to attach RFID 104 to a tire 204. Patch 300 can comprise of a base 301, and an RFID housing 302. In an embodiment wherein RFIDs 104 can be detachable, base 301 can be detached from tire 204 through an adhesive material such as a patch. Base 301 can be capable of affixing securely to tires 204. RFID housing 302 can be made of materials that include but are not limited to Acrylonitrile butadiene Styrene (ABS), Kevlar, polyethylene, and/or polyvinyl chloride. Furthermore, base 301 can comprise an orifice 303. Orifice 303 can be a hole configured to mount RFID housing 302 such that RFID housing 302 is in between orifice 303. Thus, RFID housing 302 can be capable of substantially fitting within orifice 303.

In one embodiment, RFID housing 302 can comprise an outer casing 304, and an RFID support 305 within said outer casing 304. Outer casing 304 can comprise a lip 304a configured to prevent RFID housing 302 from completely entering orifice 303. Furthermore, lip 304a can be configured to prevent RFID housing 302 from completely entering orifice 303. RFID support 305 can be capable of substantially fitting within outer casing 304. Moreover, RFID support 305 can comprise a support base 305a that rests firmly within outer casing 304 and one or more anchors 305b that directly support RFID 104. In this structure, anchors 305b can be placed on a surface of support base 305a. Further, support base 305a can substantially have the same width as the interior width of outer casing 304, such that RFID support 305 fits snugly within outer casing 304. In one embodiment, RFID support 305 can be structurally separated from the interior of outer casing 304. In another embodiment, RFID support 305 can be structurally a part of the interior of outer casing 304. Support base 305a can be positionable to maintain RFID 104 between 6-9 mm away from the tire in one embodiment. In a preferred embodiment, RFID 104 can be positionable to rest approximately 7.5 mm away from the tire. Such configuration allows RFID 104 to be read from a much greater distance than if RFID were placed closer to tire. For example, RFID communication computer 103 can be on the side of a road or checkpoint, and still read RFID 104.

RFID housing 302 can serve as a container and provide protection for RFID 104. In one embodiment, RFID housing 302 can be around 9 mm tall, 8.5 mm long, and 10 mm wide. Moreover, RFID housing 302 can mount components of RFID 104, wherein RFID 104 can comprise an RFID tag 104a and an antenna 104b. Antenna 104b can broadcast modulated signals to ensure data exchange between RFID communication computer 103 and RFID 104. Antenna 104b can transmit and receive data signals. As such, RFID tag 104a can be a transponder. Transponder can be a radar transmitter-receiver device that can automatically transmit data signals when triggered with a designated signal. RFID tag 104a can contain a unique identifier.

FIG. 3B illustrates an assembled embodiment of patch 300. Firstly, antenna 104b and RFID tag 104a can be mounted to RFID support 305. Then, RFID support 305 can be inserted into outer casing 304. RFID housing 302 can be configured with particular dimensions of an RFID 104. Antenna 104b can be attached to RFID support 305 using RFID anchors 305b. RFID support 305 can be attached to outer casing 304 from the bottom with any adhesive materials or merely stay in place by RFID support 305 tightly fitting into outer casing 304. As such, RFID tag 104a can be facing outward or toward the top of RFID housing 302. RFID housing 302 can be inserted and attached into orifice 303 of base 301 through an adhesive material or merely stay in place by tag housing 302 tightly fitting in to orifice 303.

FIG. 3C illustrates another embodiment of patch 300. In one embodiment, RFID 104 can be placed in RFID housing 302 from the top of RFID support 305. In this embodiment, RFID housing 302 can comprise outer casing 304 with a built-in RFID support 305. As such, RFID 104 can be enclosed within outer casing 304 and RFID support 305 that can secure RFID 104 in place. RFID tag 104a and antenna 104b can be attached to RFID support 305 through anchors 305b. In the embodiment shown in FIG. 3C, RFID housing 302 can further comprise a top cover 306 insertable within outer casing 304 to protect RFID 104. Furthermore, top cover 306 can be substantially the width as the interior width of outer casing 304, such that top cover 306 fits snugly within outer casing 304. An adhesive material can be used to attach top cover 306 with outer casing 304, or top cover can be manufactured to fit snugly within outer casing 304.

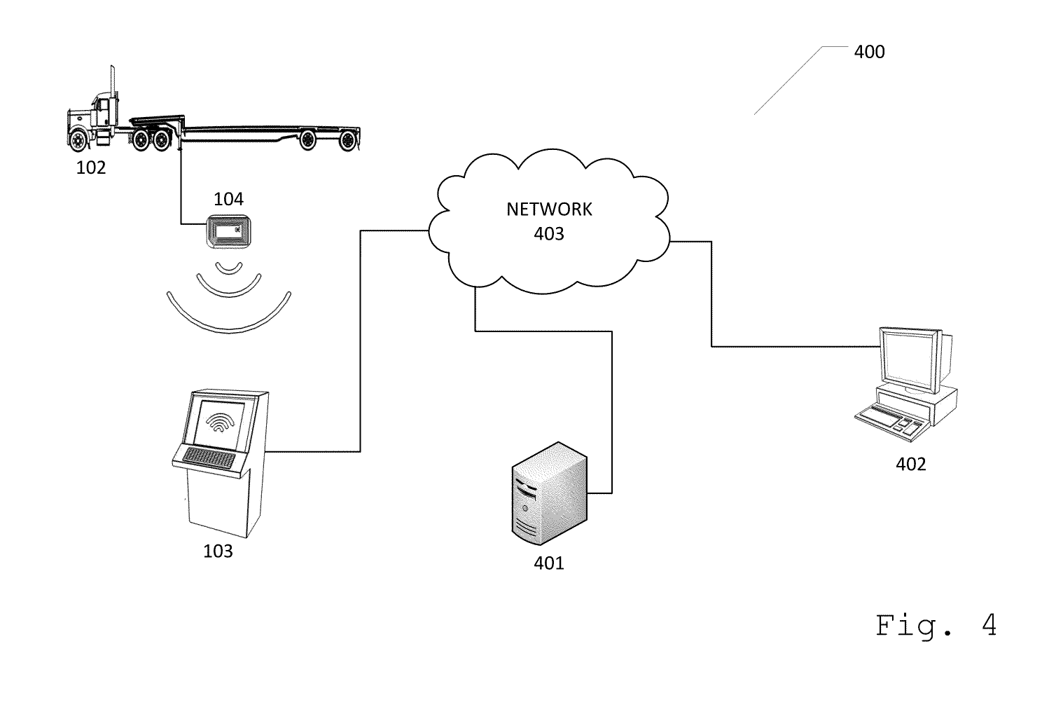

FIG. 4 illustrates a mobile depreciating asset system 400. Mobile depreciating asset system 400 can comprise RFID communication computer 103, one or more servers 401, and a plurality of computers 402 connected via a network 403. Electronic data on RFID tag 104a waits to be read. Once vehicle 102 is ready to be scanned, RFIDs 104 mounted on vehicle 102 can be read through RFID communication computer 103. Antenna 104b of RFID communication computer 103 can broadcast an electromagnetic energy to communicate with RFID tag 104a for each of RFID 104. In one embodiment, mobile depreciating asset system 400 can follow the radio regulations of ITU-R (International Telecommunications Union for Radio Communication). Thus, RFID communication computer 103 can use radio waves and frequency ranges that are reserved for RFID technology. As such, RFID communication computer 103 can be used in scanning RFIDs 104.

In one embodiment, as long as the proximity sensor on RFID communication computer 103 senses a unit, the system will continually activate the reader. Thus, when the proximity sensor no longer senses a unit, then it will send a low signal to RFID communication computer 103. As such, each RFID tags 302 can be read continuously until RFID communication computer 103 receives a low signal.

RFID tags 302 can be read periodically or aperiodically. Furthermore, receiving a steady low signal from RFID tags 302, with at least 3 seconds long will allow control system of RFID communication computer 103 to compare and throw out duplicate messages. The message can then be transmitted to server 401. As such, the message or data can be parsed and analyzed.

Further, in one embodiment vehicle 102 can be used with a mileage tracking system. In such embodiment, components of vehicle 102 can be mounted with any navigation system such as a Global Positioning System (GPS) tracking device or odometer that records number of miles travelled by each vehicle 102. For purposes of this disclosure, GPS tracking device can be an electronic device that uses radio signals between several radio towers, and/or Global Positioning System (GPS) to determine current time and location of the device. Further, odometer can be an instrument that indicates distance traveled by a vehicle. In another embodiment, other navigation system and technology, which can include but are not limited to GPS navigation routing systems, tire tread wear sensor system, Bluetooth, and voice recognition, can be used and integrated with mobile depreciating asset system 400.

In one embodiment, RFID communication computer 103 can be physically connected to a computer to be able to transmit the tag data on RFID 104. In another embodiment, RFID communication computer 103 and a computer can be a single device capable of transferring and receiving electronic data through network 403. As such, captured data information from RFID 104 can be displayed on an output device of RFID communication computer 103. In one embodiment, RFID communication computer 103 can allow an automated scanning of RFIDs 204 that is within the range of RFID communication computers 103. In another embodiment, RFID communication computers 103 can be controlled manually that can require actuation of an input device to initiate RFID communication computers 103 in scanning RFIDs 104. Server 401 can provide and perform computational tasks across network 403. Server 401 can send and receive data to and from computers 402. In one embodiment, server 401 can be a database server. In this embodiment, server 401 can also refer to a computer that hosts a database. Computer 402 can receive, store and send out data information through network 403. Computer 402 can include, but is not limited to, a laptop, desktop, tablet, or any other computing communication device capable of transmitting information data across network 403 to server 401. Network 403 can be a wide area network (WAN), or a combination of local area network (LAN), and/or piconets. Network 403 can be hard-wired, wireless, or a combination of both. A LAN can be a network within a single business while WAN can be an Internet.

FIG. 5 illustrates a schematic diagram of server 401 according to an embodiment of the present disclosure. Server 401 can comprise a device processor 501, a device memory 502, and a first local interface 503. First local interface 503 can be a program that controls a display for the user, which can allow user to view and/or interact with server 401. Server 401 can be a processing unit that performs a set of instructions stored within device memory 502. Device memory 502 can comprise a computer application 504, and a device data store 505. Computer application 504 can be a program providing logic for server 401. Device data store 505 can be collections of data accessible through computer application 504. Further, computer application 504 can perform functions such as adding, transferring, and retrieving information on device data store 505 using first local interface 503.

Further, an input data 506 or data information captured from RFID communication computers 103 can be received and analyzed by device processor 501. Processor 501 can be a device that executes programs stored in device memory 502. Memory 502 can be a physical device used to store programs and/or data. Server 401 can further comprise a communication hardware 507 can be any hardware to support communication protocols known in the art, such as hardware for packetizing data, antennas, and hardwire communication ports. Processes can include storing input data 506 to device memory 502, verifying input data 506 is valid and conforms to preset standards, or ensuring all required data. Input data 506 can be sent to communication hardware 507 for communication over network 403.

Server 401 includes at least one processor circuit, for example, having device processor 501 and device memory 502, both of which are coupled to first local interface 503. To this end, server 401 can comprise, for example, at least one server, computer or like device. First local interface 503 can comprise, for example, a data bus with an accompanying address/control bus or other bus structure as can be appreciated.

Both data and several components that are executable by device processor 501 are stored in device memory 502. In particular, computer application 504 and, potentially, other applications are stored in the device memory 502 and executable by device processor 501. Also, device data store 505 and other data can be stored in device memory 502. In addition, an operating system can be stored in device memory 502 and executable by device processor 501.

Other applications can be stored in device memory 502 and executable by device processor 501. Where any component discussed herein is implemented in the form of software, any one of a number of programming languages can be employed such as, for example, C, C++, C#, Objective C, Java, Java Script, Perl, PHP, Visual Basic, Python, Ruby, Delphi, Flash, or other programming languages.

A number of software components can be stored in device memory 502 and can be executable by device processor 501. In this respect, the term “executable” can mean a program file that is in a form that can ultimately be run by device processor 501. Examples of executable programs can include a compiled program that can be translated into machine code in a format that can be loaded into a random access portion of device memory 502 and run by device processor 501, source code that can be expressed in proper format such as object code that is capable of being loaded into a random access portion of device memory 502 and executed by device processor 501, or source code that can be interpreted by another executable program to generate instructions in a random access portion of device memory 502 to be executed by device processor 501, etc. An executable program can be stored in any portion or component of device memory 502 including, for example, Random Access Memory (RAM), Read-Only Memory (ROM), hard drive, solid-state drive, USB flash drive, memory card, optical disc such as compact disc (CD) or digital versatile disc (DVD), floppy disk, magnetic tape, or other memory components.

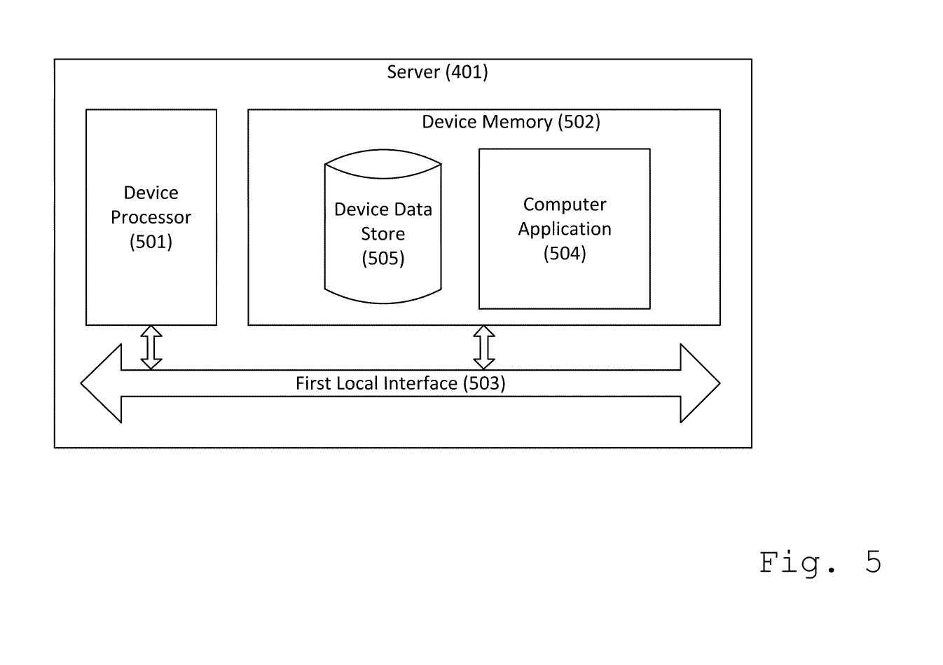

FIG. 6 illustrates device data store 505 comprising a plurality of items 601, a plurality of system users 602, one or more notifications 603, a time and date of scan 604, a scan location 605, an inventory 606, and a distance tally 607. In this embodiment, items 601 can be a list of components of vehicles 102. As such items 601 can be a list of tagged units, which can include but are not limited to tractors, trailers, and tires. Further, items 601 can either be identified as a parent item 601a or a child item 601b.

Parent items 601a can refer to the main component of vehicle 102, which is tractor 201. As such in the hierarchy of vehicle 102, tractor 201 can be parent item 601a of trailer 202. Furthermore, tractor 201 can be parent item 601a to tires 204 on wheels 203a and 203b. Similarly, trailer 202 can be parent item 601a to tires 204 wheels 203c to 203r.

Child items 601b can refer to component assigned under parent item 601a. Thus in the hierarchy of vehicle 102, trailer 202 can be child item 601b of tractor 201. Moreover, wheels 203a and 203b on tractor 201 can be child item 601b of tractor 201. Likewise, wheels 203c up to wheels 203r attached on trailer 202 can be child item 601b of trailer 202.

System users 602 can be a list of users authorized to access, and manage mobile depreciating asset system 400. Furthermore, system user 602 can be the person permitted to perform necessary actions on items 601. Moreover, system user 602 can comprise user information that can include but are not limited to a unique user (ID) identity, name, email address, and contact details.

Notifications 603 can be messages or alerts that are sent to designated system user 602 when inconsistent activities has been monitored. Inconsistent activities can be the discrepancies captured when RFID tags 302 are compared with the data stored within server 401. Therefore, inconsistent activities can include inactivity of item 601, item 601 is with unassigned group, and item 601 is tagged with the wrong group. Furthermore, notifications 603 can comprise information such as item's unique identification, date and time activity is captured, item's associated group, and other information associated to item 601 being reported. Further, each notification 603 can be assigned to specific system users 602.

Time and date of scan 604 can be the date and time wherein activities applied to item 601 can be recorded. Activities recorded can include scanning, installation, and registration of items 601. Location 605 can be the place or department wherein items 601 are installed, registered, or scanned through RFID communication computer 103. In one embodiment, location 605 can be the place where RFID communication computer 103 is located. Moreover, location 605 can be used to uniquely identify the points wherein activities on items 601 are executed. Further, in an embodiment wherein vehicles 102 comprise a mileage tracking system, distance traveled 607a by vehicle 102 from location 605 to another location can also be checked and sent to the system while RFID tags 302 are being scanned.

Inventory 606 can be the list and quantities of each item 601 within fleet facility 100. As such, quantities, of parent item 601a and child item 601b can be itemized and monitored. In one embodiment, inventory 606 can comprise an in-stock 606a, an in-use 606b, and an in-repair 606c. In-stock 606a can be the list of item 601 that are in good condition and are available to be used as a replacement for other items 601 that are either damaged or in repair. As such, in-stock 606a can be repaired item 601 or a brand new item 601. In-use 606b can be items 601 that are currently deployed for service. In one embodiment, inventory 606 can also comprise a list for item 601 that left and returned within fleet facility 100. As such, vehicles 102 can comprise a sensor system that can allow mobile depreciating asset system 400 to record the number of incoming and outgoing vehicles 102 within fleet facility 100. In repair 606c can be list of item 601 that are currently being repaired or is under warranty but haven't been replaced yet.

In an embodiment wherein vehicles 102 can be mountable with a mileage tracking system and items 601 can each comprise a tracking device, a distance tally 607 can be recorded. Distance tally 607 can be the total mileage travelled by each item 601. Distance tally 607 can comprise distance traveled 607a, which can be the measure of distance for each item 601. Thus, distance traveled 607a of parent items 601a must be the same with distance traveled 607a of child items 601b. Thus when vehicles 102 pass RFID communication computers 103, distance traveled 607a for parent items 601a and child items 601b of a vehicle can be checked and compared through the system. Therefore, the system can monitor if any of items 601 are missing or moved. In such scenario, notification 603 can be generated and sent to the designated system users 602. If a child item gets removed and placed on a different parent item, then it can keep its historical distance traveled 607a but begin tallying according to the new parent item 601a.

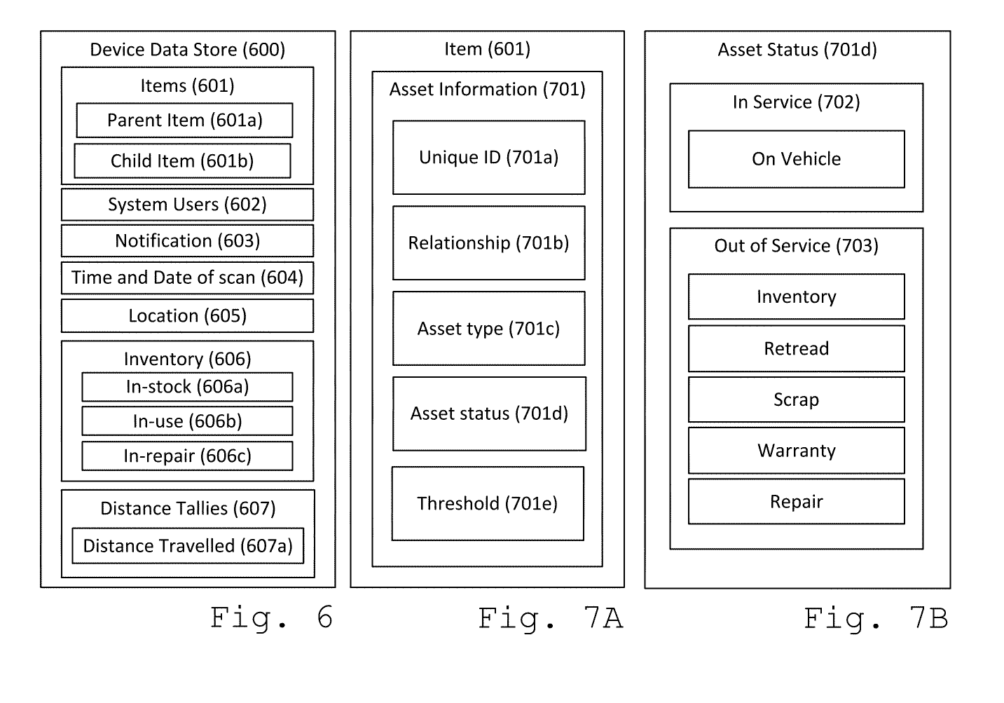

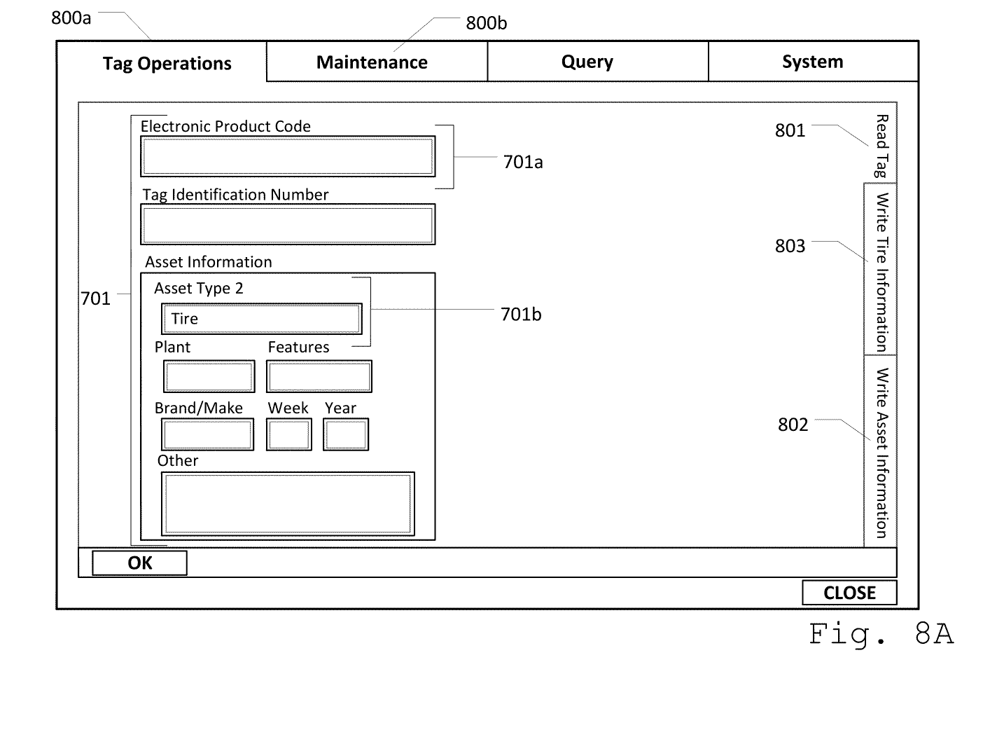

FIG. 7A illustrates items 601 comprising asset information 701. Asset information 701 can comprise any information associated. Asset information 701 can comprise a unique (identifier) ID 701a, a relationship 701b, an asset type 701c, an asset status 701d, and a predetermined threshold 701e. Unique ID 701a can be a unique code assigned to item 601. In one embodiment, unique ID 701a can be a tag (Identification) ID 704. Tag ID 704 can be related to a unique identifier stored in each RFID tag 104a. In an embodiment wherein item 601 is tire 204, unique ID 701a can be a DOT (Department of Transportation) tire identification number. In another embodiment wherein item 601 is tractor 201 or trailer 202, unique ID 701a can be a vehicle identification number.

Relationship 701b can be a group (ID) identifier relatable to a unique position of child items 601b on parent items 601a. Furthermore, relationship 701b can identify how item 601 can be connected to a vehicle. As such, relationship 701b can provide information on hierarchy level of item 601. As such, relationship 701b can be used to identify item 601 as parent item 601a or child item 601b. Moreover, relationship 701b can be associated as parent identifier (ID), wherein unique ID 701a that is assigned to the parent of item 601 can be the component ID applied on said item 601. As an example, relationship 701b assigned to tires 204a to 204r can be the unique ID assigned to vehicle 102. This can show that tire 204a up to tire 204r is a child item of vehicle 102. Further, when item 601 is tractor 201 relationships 701b can be displayed as null or empty to indicate that the item is parent item 601a and is the top most hierarchy. In such assignments, items 601 can be grouped and identified according to a parent-child relationship. Therefore, when item 601 in a group is missing, item 601 can be easily identified and the system can allow notification 603 be sent to alert the assigned system user 602. Asset type 701c can be the category of items 601 economic value for a company. Thus asset type 701c can include categories such as tractor/semi-truck, trailer, or tire. Asset status 701d can be the current standing of item 601. Predetermined threshold 701e can be a grade rating for tires 204. As such, predetermined threshold for tires 204 can include but are not limited to tire treadwear, traction performance, and temperature resistance. In one embodiment, predetermined threshold 701c can be universal for tires 204 attached to the same parent item 601a. As such, each tire 204 or multiple tires 204 that are associated to the same parent item 601a can have the same predetermined threshold. In another embodiment, predetermined threshold 701c can be unique for each child item 601b.

FIG. 7B illustrates asset status 701d comprising an in service status 702 and an out of service status 703. For purposes of this disclosure, asset status 701d discussed herein only pertains to child item 601b. Further, in service status 702 can comprise status description of an on vehicle while an out of service status 703 can comprise status description of an inventory, a retread, a scrap, a warranty, and a repair status. In an embodiment wherein item 601 can be tire 204, on vehicle status can mean that tire 204 is currently attached on vehicle 102 and being used to perform a job. Moreover, in this embodiment tire mileage for each tire 204 can be tracked. Furthermore, items 601 with on vehicle status can be listed and be counted as in-use 606b under inventory 606. Further when tire 204 is in out of service status 703 and status description is inventory, item 601 can be in good condition and is waiting to be attached to vehicle 102. As such, items 601 can be included in in-stock 606a. Furthermore, item 601 can be changed to in service status 702 once item 601 is attached to vehicle 102. Thus, item 601 can be removed from in-stock 606a and be added into in-use 606b. In this embodiment when status description is set on retread, this can mean that tread of tire 204 had been damaged. Thus, item 601 can be removed and sent to a tire shop to have it repaired. Also, item 601 can be counted under in-repair 606c under inventories 606. Moreover, when status description of item 601 is set to scrapped, item 601 can be beyond repair and must be discarded. As such, tire 204 can be completely removed from vehicle 102. When item 601 can be beyond repair, item 601 can be totally removed from inventory 606. Furthermore, when status description is set on warranty, item 601 can be defected but is covered under warranty thus item 601 can be replaced with a new tire. In one embodiment, item 601 in warranty status can be added under in-repair 606c under inventory 606. As such, when item 601 is not covered by warranty then item 601 can be removed from inventory 606. But if item 601 is replaced with a new item 601 then item 601 can be removed from in-repair status 606c and be added into in-stock 606a inventory. Moreover in the embodiment wherein distance traveled 607a is tracked for each tire 204, the mileage information can be used to know that a specific tire is still under warranty. Lastly, when status description is set on repair, then item 601 has some damages (other than retread) and can still be repaired. This means that the damage is not covered by warranty or item 601 is not under warranty. Damage can include but are not limited to punctured tire, flat tires, cuts, abrasions, etc.

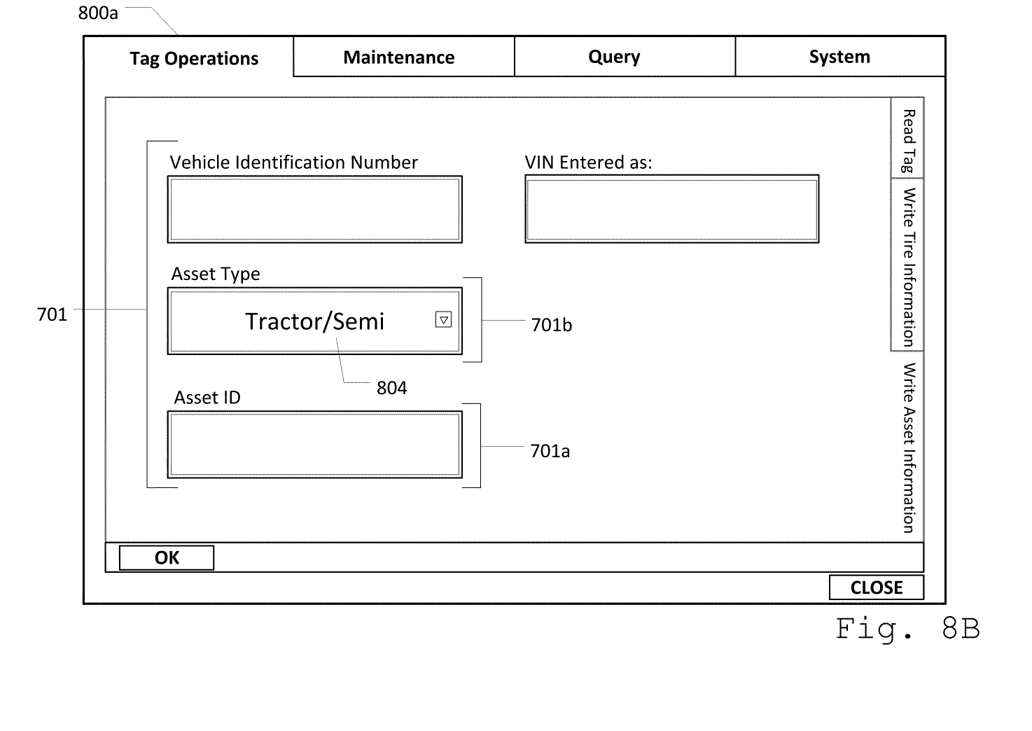

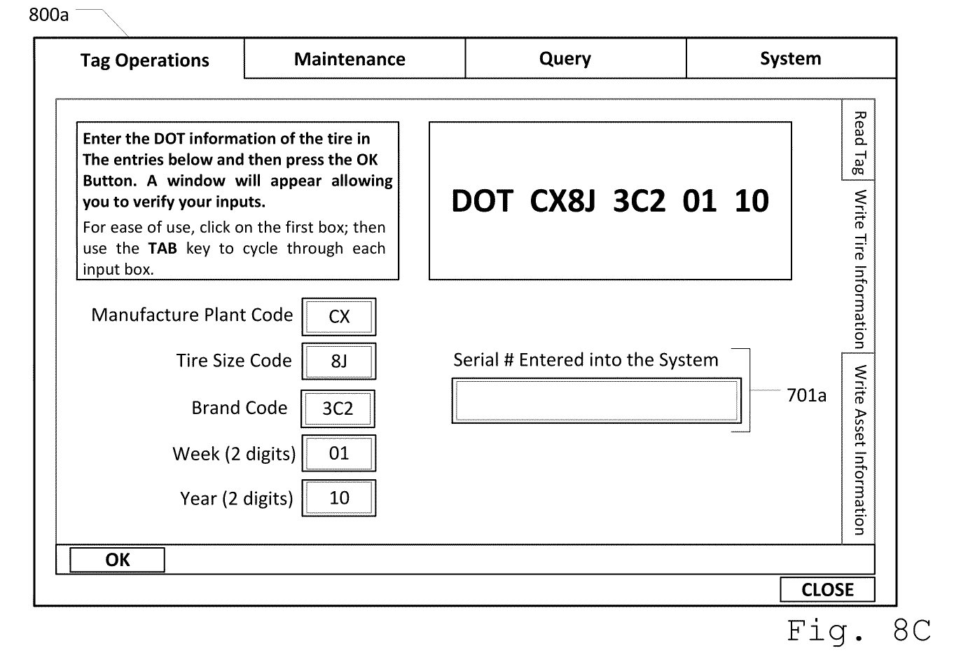

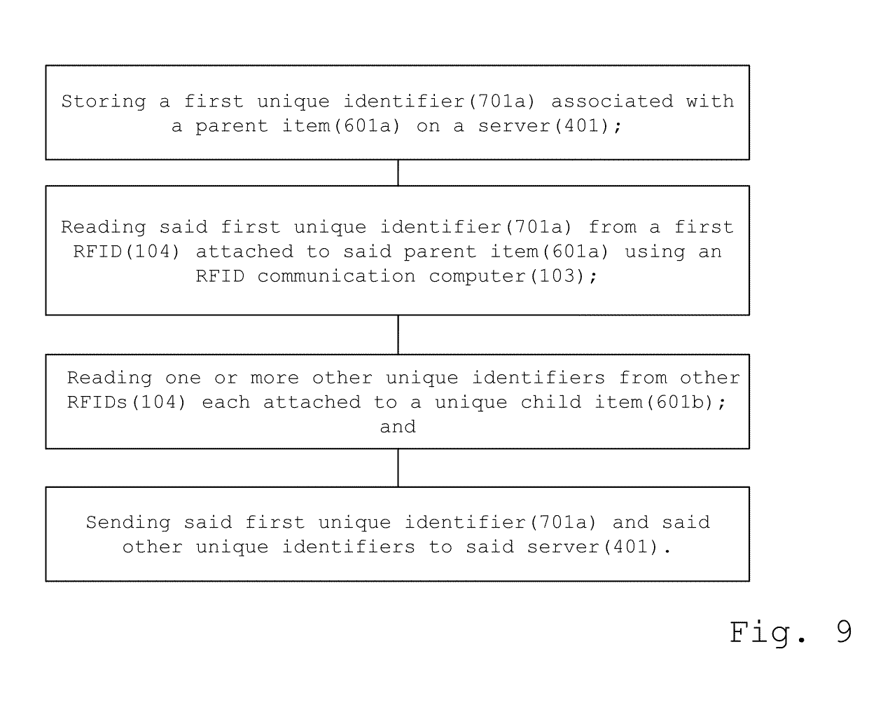

FIG. 8A illustrates a tag operation mode screen 800a that displays a read tag tab 801. In an embodiment wherein RFID communication computer 103 can be connected to a computer 402, tag operation screen 800a can be displayed on a screen of computer 402. In another embodiment wherein RFID communication computer 103 and computer 402 can be a single device, tag operation 800a can be displayed on a screen of RFID communication computer 103. Further, tag operation screen 800a can comprise read tag tab 801, a write asset information tab 802 and a write tire information tab 803. Read tag tab 801 can be a user interface that allows a system user 602 to read asset information 701 transmitted from RFID tag 104a of each item 601. Read tag tab 801 can display unique ID 701a, asset type 701c, and other asset information 701 such as manufacturer plant code, asset features, brand code, week and year item was made. In one embodiment, unique ID 701a can be an electronic product code of item 601. Further under read tag tab 801, asset information 701 can only be read. Thus, information displayed on read tag tab 801 cannot be deleted, or updated. Further, a maintenance screen 800b can also be accessed from tag operation screen 800a. Maintenance screen 800b can allow system user to update, and record changes made for each item 601, such as asset status 701d. Furthermore, changes made on maintenance screen 800b can be stored as a historical data. Thus, historical data can be lists of past information on each item 601.

FIG. 8B illustrates a tag operation screen 800a that displays a write asset information tab 802. Under this tab, system user 602 can be allowed to enter asset information 701. As such, asset information 701 can be written to RFID tag 104a as tag data 804. Moreover, asset information 701 under write asset information tab 802 can comprise a unique ID 701a, a vehicle identification (VIN) number, and asset type 701c. For purposes of this disclosure, vehicle identification number can be a unique code comprising a serial number that can identify each vehicle 102. Further in this embodiment, unique ID 701a can be an asset ID. Asset ID can be a unique code assigned to an asset. Under write asset information tab 802, system user 602 can enter information on the screen such as unique ID 701a, VIN number, and asset type 701c and then click OK to transmit information entered. As such, RFID communication computer 103 can read RFID tag 104a. Then data information stored in RFID tag 104a and data entered on write asset information tab 802 can be compared. If tag data 804 already exists then the system user 602 will be asked to overwrite the information but when tag data 804 does not exist, tag data 804 is inserted into the system.

FIG. 8C illustrates a tag operation screen 800a that displays a write tire information tab 803. This tab can allow user to enter tire information in the system. In this screen, unique ID 701a for tire 204 can be DOT tire number. Further wherein DOT tire number can indicate information on tire 204 such as the tire's manufacturing plant, tire size, tire brand, week and year tire is made. Further under this tab, asset type 701c can be automatically configured to tire.

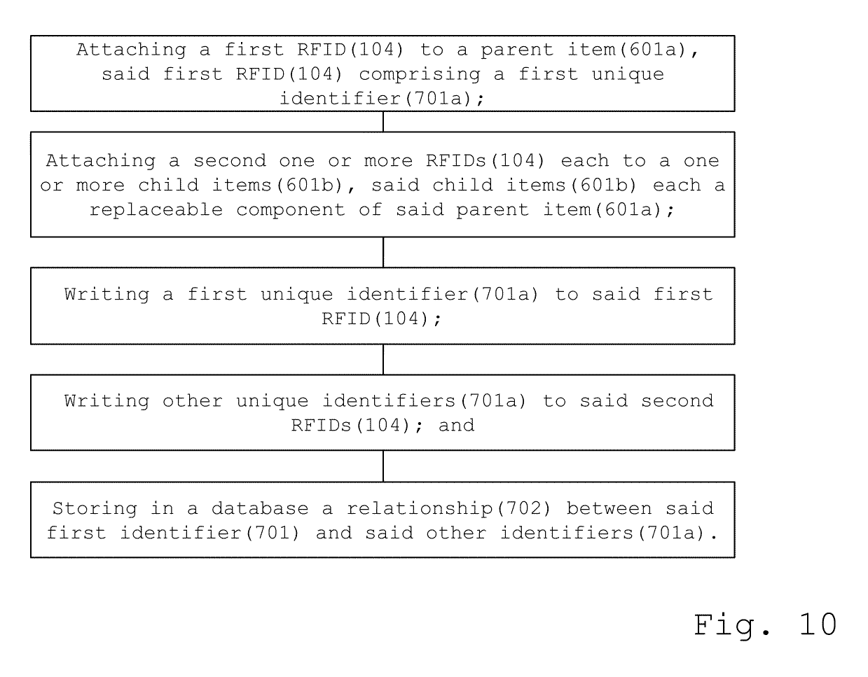

FIG. 9 illustrates an exemplary method for tracking consumable items 601. In this embodiment, consumable items 601 can be tires 204. A first unique ID 701a associated with a parent item 601a can first be stored on a server 401. When a vehicle 102 passes an RFID communication computer 103, first unique ID 701a from a first RFID 104 attached to parent item 601a can be read. This can allow tracking of assets or parent item 601a. In one embodiment, first unique identifier is a vehicle identification number. In another embodiment, first unique identifier is an asset (ID) identifier. Further, RFID communication computer 103 can also be used to read one or more other unique identifiers 701a from other RFIDs 104 each attached to a unique child item 601b. In this embodiment other unique identifier 701a is a Department of Transportation (DOT) tire identification number. First unique identifier 701a and other unique identifiers 701a can then be sent to server 401. In an embodiment wherein a mileage tracking system is attached to parent item 601a, a server 401 can also receive a distance traveled over a network 403. As such, distance traveled 607a can be added to distance tallies 607 on server 401. Distance tallies 607 can be associated with each of child item 601b associated with parent item 601a. Distance tallies 607 can be read through RFID communication computer 103 and be sent to server 401 through network 403, in one embodiment. Additionally, when distance tallies 607 meets or exceeds a predetermined threshold 701e for any of child item 601b, a notification 603 can be sent to notify a designated system user 602. Further, server 401 can determine whether other unique identifiers 701a represents a complete set of identifiers associated with first unique identifier. As such, server 401 can determine if child item 601b is missing or moved. Thus, notification 603 can be sent when complete set of identifiers associated with first unique identifier is missing. Moreover, when distance tallies 607 for any of child items 601b does not match distance travelled 607 of parent item 601b notification 603 can also be sent to assigned system user 602.

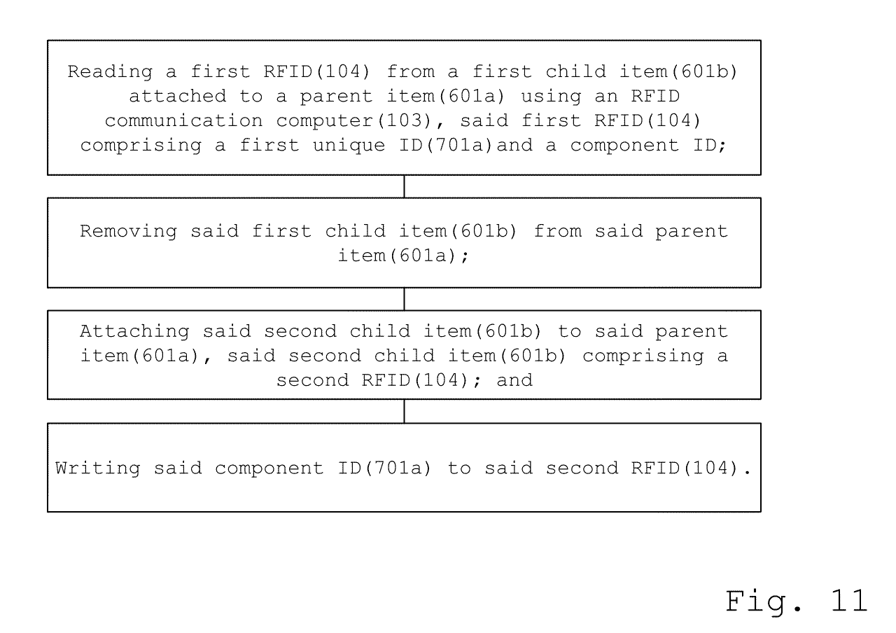

FIG. 10 illustrate an exemplary method for setting up a mobile depreciating asset system 400. A first RFID 104 can be attached to a parent item 601a wherein first RFID can comprise a first unique ID 701a. In one embodiment, first ID 701a can be a VIN number or other identification method. In another embodiment, first unique ID 701a can be an asset (ID) identifier. Then, a second one or more RFIDs 104 can be attached each to one or more child items 601b. The child items 601b can each be a replaceable component of parent item 601a. When a system user 602 needs to change an asset status 701d of an item 601, system user 602 must first scan the item whose asset status 701d should be changed. As such, RFID communication computer 103 can first be placed in a maintenance mode. In one embodiment, accessing a maintenance screen 800b can allow system user 602 to place RFID communication computer 103 into maintenance mode. Maintenance mode can allow the system to record changes made for each item 601 and store the information as a historical data. In one embodiment, an add button can be clicked on maintenance screen 800b to indicate that item 601 is to be added. Once RFID communication computer 103 is ready, first unique ID 701a can be written on first RFID 104.

Once first unique ID 701a is scanned, other unique ID 701a can be written on second RFIDs 104. Other unique identifiers each comprise first unique ID, in one embodiment. Further in one embodiment, other ID 701a can be entered into the system by using an RFID communication computer 103. In this embodiment, unique ID 701a and other asset information 701 can automatically be captured and stored in the system. In another embodiment, unique ID 701a can be entered into the system by manually entering the data using computers 402. In this embodiment, authorized system user 602 can manually enter unique ID 701a and other asset information 701 through computer 402. Moreover, during each scan of RFID tags 104a using RFID communication computer 103, information such as system user 602, time and date of scan 604 and location 605 are captured. In one embodiment, RFID communication computer 103 can send instructions to the system and indicate location 605 where child item 601b can be installed. As such, vehicle 102 can receive instructions from RFID communication computer 103a location 605 to attach each of tires 204. After assigning second unique ID 701a to second RFIDs 104, a relationship 701b between first unique ID 701a and other unique ID 701a can be stored in a database. Once data information is stored in database, child item 601b can then be installed to parent item 601a.

FIG. 11 illustrates an exemplary method for removing a child item 601b from a parent item 601a. Child item 601b can wear out through use. In this scenario, a first child item 601b can be removed. Thus, a second child item 601b can be attached to a parent item 601a to replace first child item 601b. Therefore to remove first child item 601b attached to parent item 601a, a first RFID 104 from first child item 601b can first be read using an RFID communication computer 103. First RFID 104 can comprise a first unique ID 701a and a component ID. First unique ID 701a can be a DOT tire identification number, in one embodiment. Once scanned, asset information 701 can be displayed on a tag operations screen 800a. A system user 602 can then access a maintenance screen 800b to change the status of first child item 601b. As such, RFID communication computer 103 can be placed in a maintenance mode. This can allow the system to record the changes made on asset status 701d of each item 601. On maintenance mode, system user 602 can change asset status 701d of first child item 601b from an in service status 702 to an out of service status 703. Moreover, system user 602 can indicate the reason or description for status change. Reason for status change can be because of retread, scrapped, warranty, or repair. In one embodiment, first child item 601b can be removed from the system by clicking a remove button on maintenance screen 800b.

As such, first child item 601b can be removed from an inventory 606 but asset information 701 on removed first child item 601b can still be stored as a historical data. In this embodiment, mobile depreciating asset system 400 can compare new tag data 804 with historical data of items 601 stored in device data store 505, to determine any inconsistencies. When reason of change in asset status 701d is scrap, all information associated to scrapped item can be removed but information can still be stored in historical data. Further, a notification 603 can be sent to an assigned system user 602 once an inconsistency is found. Inconsistencies can include item 601 is missing from vehicle 102, the distance recorded for child item 601b is different with distance traveled 607a by parent item 601a, item 601 is attached to wrong vehicle, or position of item 601 is incorrect. In another embodiment, notification 603 can be sent to the designated system user 602 when a low in-stock 606a is detected by the system. As such, system user 602 that received notification 603 can order or purchase items 601 that are low in stock.

Once asset status 701d is updated, system user 602 can then scan parent item 601a. This can also allow the system to record a time and date of scan 604 and a location 605 wherein parent item 601a is scanned. After the scan, first child item 601b can then be removed from parent item 601a. To replace first child item 601b, system user 601 can click a replace button on maintenance screen 800b and then scan second child item 601b through RFID communication computer 103. This can allow RFID tag 104a on second child item 601b be read and stored in the system. After scanning child item 601b, parent item 601a can then be scanned by RFID communication computer 103. Once items 601 are scanned, second child item 601b can be attached to parent item 601a. Second child item 601b can comprise a second RFID 104. Component ID can then be written to second RFID 104. As such, second child item 601b can acquire component ID of first child item 601b.

Device memory 502 can include both volatile and nonvolatile memory and data storage components. Volatile components do not retain data values upon loss of power. Nonvolatile components, on the other hand, retain data upon a loss of power. Thus, device memory 502 can comprise, for example, Random Access Memory (RAM), Read-Only Memory (ROM), hard disk drives, solid-state drives, USB flash drives, memory cards accessed via a memory card reader, floppy disks accessed via an associated floppy disk drive, optical discs accessed via an optical disc drive, magnetic tapes accessed via an appropriate tape drive, and/or other memory components, or a combination of any two or more of these memory components. In addition, the RAM can comprise, for example, Static Random Access Memory (SRAM), Dynamic Random Access Memory (DRAM), or Magnetic Random Access Memory (MRAM) and other such devices. The ROM can comprise, for example, a Programmable Read-Only Memory (PROM), an Erasable Programmable Read-Only Memory (EPROM), an Electrically Erasable Programmable Read-Only Memory (EEPROM), or other like memory device.

Also, device processor 501 can represent multiple device processors 501. Likewise, device memory 502 can represent multiple device application memories 502 that operate in parallel processing circuits, respectively. In such a case, first local interface 503 can be an appropriate network, including network 403 that facilitates communication between any two of the multiple device processors 501, between any device processor 501 and any of the device memory 502, or between any two of the device memory 502, etc. First local interface 503 can comprise additional systems designed to coordinate this communication, including, but not limited to, performing load balancing. Device processor 501 can be of electrical or of some other available construction.

Although computer application 504, and other various systems described herein can be embodied in software or code executed by general purpose hardware discussed above, computer application 504 can also be embodied in dedicated hardware or a combination of software/general purpose hardware and dedicated hardware. If embodied in dedicated hardware, each computer application 504 can be implemented as a circuit or state machine that employs a number of technologies. These technologies can include, but are not limited to, discrete logic circuits having logic gates for implementing various logic functions upon an application of one or more data signals, application specific integrated circuits having appropriate logic gates, or other components, etc. Such technologies are generally well known by those skilled in the art and, consequently, are not described in detail herein.

The flowchart of FIG. 9 and FIG. 10 shows the functionality and operation of an implementation of portions of computer application 504. If embodied in software, each block can represent a module, segment, or portion of code that comprises program instructions to implement the specified logical function(s). The program instructions can be embodied in the form of source code that comprises human-readable statements written in a programming language or machine code that comprises numerical instructions recognizable by a suitable execution system such as device processor 501 in a computer system or other system. The machine code can be converted from the source code, etc. If embodied in hardware, each block can represent a circuit or a number of interconnected circuits to implement the specified logical function(s).

Although the flowchart of FIGS. 9 and 10 show a specific order of execution, the order of execution can differ from what is depicted. For example, the order of execution of two or more blocks can be rearranged relative to the order shown. Also, two or more blocks shown in succession in FIGS. 9 and 10 can be executed concurrently or with partial concurrence. In addition, any number of counters, state variables, warning semaphores, or messages might be added to the logical flow described herein, for purposes of enhanced utility, accounting, performance measurement, or providing troubleshooting aids, etc. All such variations are within the scope of the present disclosure.

Also, any logic or application described herein that comprises software or code, including computer application 504, can be embodied in any computer-readable storage medium for use by or in connection with an instruction execution system such as, device processor 501 in a computer system or other system. The logic can comprise statements including instructions and declarations that can be fetched from the computer-readable storage medium and executed by the instruction execution system.

In the context of the present disclosure, a “computer-readable storage medium” can be any medium that can contain, store, or maintain the logic or application described herein for use by or in connection with the instruction execution system. The computer-readable storage medium can comprise any one of many physical media, such as electronic, magnetic, optical, electromagnetic, infrared, or semiconductor media. More specific examples of a suitable computer-readable storage medium can include, but are not limited to, magnetic tapes, magnetic floppy diskettes, magnetic hard drives, memory cards, solid-state drives, USB flash drives, or optical discs. Also, the computer-readable storage medium can be a Random Access Memory (RAM), including Static Random Access Memory (SRAM), Dynamic Random Access Memory (DRAM), or Magnetic Random Access Memory (MRAM) and other such devices. The ROM can comprise, for example, a Programmable Read-Only Memory (PROM), an Erasable Programmable Read-Only Memory only memory (PROM), an erasable programmable read-only memory (EPROM), an electrically erasable programmable read-only memory (EEPROM), or other type of memory device.

It should be emphasized that the above-described embodiments of the present disclosure are merely possible examples of implementations set forth for a clear understanding of the principles of the disclosure. Many variations and modifications can be made to the above-described embodiment(s) without departing substantially from the spirit and principles of the disclosure. All such modifications and variations are intended to be included herein within the scope of this disclosure and protected by the following claims.

Various changes in the details of the illustrated operational methods are possible without departing from the scope of the following claims. Some embodiments may combine the activities described herein as being separate steps. Similarly, one or more of the described steps may be omitted, depending upon the specific operational environment the method is being implemented in. It is to be understood that the above description is intended to be illustrative, and not restrictive. For example, the above-described embodiments may be used in combination with each other. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.”

1. A system for attaching RFIDs on a tire comprising
A base comprising an orifice, said base capable of affixing to a tire; and
An RFID housing capable of substantially fitting within said orifice

2. The system of claim 1 wherein said RFID housing comprises
an outer casing; and
an RFID support capable of substantially fitting within said outer casing.

3. The system of claim 2 wherein said outer casing comprises a lip configured to prevent RFID housing from completely entering said orifice.

4. The system of claim 2 wherein said RFID support comprises
a support base; and
one or more anchors on a surface of said support base.

5. The system of claim 4 wherein said support base is substantially the same width as the interior width of said outer casing, such that said RFID support fits snugly within said outer casing.

6. The system of claim 2 wherein said RFID support is structurally separated from the interior of said outer casing.

7. The system of claim 2 wherein said RFID support is structurally a part of the interior of said outer casing.

8. The system of claim 6 wherein said RFID housing further comprises a top cover insertable within said outer casing.

9. The system of claim 8 wherein said top cover is substantially the width as the interior width of said outer casing, such that said top cover fits snugly within said outer casing.

10. The system of claim 2 wherein said RFID support is positionable to maintain an RFID tag between six millimeters and nine millimeters away from said tire.

11. The system of claim 2 wherein said RFID support is positionable to maintain an RFID tag 7.5 millimeters away from said tire.

12. The system of claim 1 wherein said first RFID housing comprises an acrylonitrile butadiene styrene (ABS) plastic.

13. The system of claim 1 wherein said first RFID housing comprises Kevlar.

14. The system of claim 1 wherein said first RFID housing comprises polyethylene.

15. The system of claim 1 wherein said first RFID housing comprises polyvinyl chloride.
